(19) United States
(12) Patent Application Publication
(10) Pub. No.: US 2011/0304652 A1
(43) Pub. Date: Dec. 15, 2011

(54) ELECTRONIC DISPLAY

(76) Inventors: Vincent C. Korthuis, Corvallis, OR (US); Jong-Souk Yeo, Corvallis, OR (US)

(21) Appl. No.: 13/032,234

(22) Filed: Feb. 22, 2011

Related U.S. Application Data
(63) Continuation-in-part of application No. 12/815,811, filed on Jun. 15, 2010.

(51) Int. Cl. G09G 3/34; G09G 5/02; H01L 21/28

(52) U.S. Cl. 345/690; 438/34; 257/E21.158; 345/107

(57) ABSTRACT

An electronic display includes a first display element configured to control a first colorant and a second display element stacked on the first display element and configured to control a second colorant. The electronic display also includes first, second, and third transparent substrates. The first display element includes a continuous first electrode on a first side of the first substrate, a plurality of first thin film transistors on the second substrate, and a plurality of second electrodes on the second substrate. Each second electrode is coupled to a first thin film transistor. The second display element includes a continuous third electrode on a second side of the first substrate, a plurality of second thin film transistors on the third substrate, and a plurality of fourth electrodes on the third substrate. Each fourth electrode is coupled to a second thin film transistor.

### CROSS-REFERENCE TO RELATED PATENT APPLICATION

This patent application is a continuation-in-part of U.S. patent application Ser. No. 12/815,811, entitled “DISPLAY ELEMENT” and filed Jun. 15, 2010, which is incorporated herein by reference.

### BACKGROUND

Electrophoresis is the translation of charged objects in a fluid in response to an electric field. Electrophoretic inks are useful as a medium to enable bistable, low power types of displays. Conventional electrophoretic displays feature either black and white states (by exchanging white and black charged colorant particles at the top of the display cell) or white and colored states (by moving white colorant particles in a dyed fluid up and down electrophoretically). These conventional electrophoretic displays cannot be easily extended to provide full-color displays or large format displays.

### BRIEF DESCRIPTION OF THE DRAWINGS

FIG. 1A illustrates a cross-sectional view of one embodiment of an electro-optical display.

FIG. 1B illustrates a cross-sectional view of another embodiment of an electro-optical display.

FIG. 1C illustrates a cross-sectional view of another embodiment of an electro-optical display.

FIG. 2A illustrates a top view of one embodiment of an electrode for an electro-optical display.

FIG. 2B illustrates a top view of another embodiment of an electrode for an electro-optical display.

FIG. 2C illustrates a top view of another embodiment of an electrode for an electro-optical display.

FIG. 2D illustrates a top view of another embodiment of an electrode for an electro-optical display.

FIG. 2E illustrates a top view of another embodiment of an electrode for an electro-optical display.

FIG. 2F illustrates a top view of another embodiment of an electrode for an electro-optical display.

FIG. 2G illustrates a top view of another embodiment of an electrode for an electro-optical display.

FIG. 3A illustrates a top view of one embodiment of a dot region of an electrode within an electro-optical display.

FIG. 3B illustrates a top view of another embodiment of a dot region of an electrode within an electro-optical display.

FIG. 3C illustrates a top view of another embodiment of a dot region of an electrode within an electro-optical display.

FIG. 3D illustrates a top view of another embodiment of a dot region of an electrode within an electro-optical display.

FIG. 3E illustrates a top view of another embodiment of a dot region of an electrode within an electro-optical display.

FIG. 4 illustrates a view of a portion of one embodiment of an electro-optical display.

FIG. 5A illustrates a cross-sectional view of another embodiment of an electro-optical display.

FIG. 5B illustrates a top view of one embodiment of electrodes for the electro-optical display illustrated in FIG. 5A.

FIG. 6A illustrates a cross-sectional view of one embodiment of an electro-optical display in a clear optical state.

FIG. 6B illustrates a cross-sectional view of one embodiment of an electro-optical display in a first color optical state.

FIG. 6C illustrates a cross-sectional view of one embodiment of an electro-optical display in a second color optical state.

FIG. 7A illustrates a top view of one embodiment of electrodes for a dual color electro-optical display.

FIG. 7B illustrates a top view of another embodiment of electrodes for a dual color electro-optical display.

FIG. 8A illustrates a cross-sectional view of one embodiment of an electro-optical display in a clear optical state.

FIG. 8B illustrates a cross-sectional view of one embodiment of an electro-optical display in a first color optical state.

FIG. 8C illustrates a cross-sectional view of one embodiment of an electro-optical display in a second color optical state.

FIG. 9 illustrates a top view of one embodiment of a pixelated electro-optical display.

FIG. 10 illustrates a top view of another embodiment of a pixelated electro-optical display.

FIG. 11A illustrates a top view of another embodiment of a pixelated electro-optical display.

FIG. 11B illustrates a first cross-sectional view of the pixelated electro-optical display illustrated in FIG. 11A.

FIG. 11C illustrates a second cross-sectional view of the pixelated electro-optical display illustrated in FIG. 11A.

FIG. 12 illustrates a cross-sectional view of another embodiment of an electro-optical display.

FIG. 13 illustrates a cross-sectional view of another embodiment of an electro-optical display.

FIG. 14 illustrates a cross-sectional view of one embodiment of a full color electro-optical display.

FIG. 15 illustrates a cross-sectional view of another embodiment of a full color electro-optical display.

FIG. 16 illustrates a cross-sectional view of another embodiment of a full color electro-optical display.

FIG. 17 illustrates one embodiment of an electronic display including two electro-optic layers.

FIG. 18 illustrates another embodiment of an electronic display including two electro-optic layers.

FIG. 19 illustrates another embodiment of an electronic display including two electro-optic layers.

FIG. 20 illustrates a cross-sectional view of one embodiment of an electronic display including two electro-optic layers.

FIG. 21 illustrates a cross-sectional view of another embodiment of an electronic display including two electro-optic layers.

FIG. 22 illustrates a cross-sectional view of another embodiment of an electronic display including two electro-optic layers.

FIG. 23 illustrates a cross-sectional view of another embodiment of an electronic display including two electro-optic layers.

FIG. 24 illustrates a cross-sectional view of another embodiment of an electronic display including two electro-optic layers.

### DETAILED DESCRIPTION

In the following detailed description, reference is made to the accompanying drawings which form a part hereof, and in which is shown by way of illustration specific embodiments in which the disclosure may be practiced. In this regard, directional terminology, such as “top,” “bottom,” “front,” “back,” “leading,” “trailing,” etc., is used with reference to the orientation of the Figure(s) being described. Because components of embodiments of the present disclosure can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

As used herein, the term “over” is not limited to any particular orientation and can include above, below, next to, adjacent to, and/or on. In addition, the term “over” can encompass intervening components between a first component and a second component where the first component is “over” the second component.

As used herein, the term “adjacent” is not limited to any particular orientation and can include above, below, next to, and/or on. In addition, the term “adjacent” can encompass intervening components between a first component and a second component where the first component is “adjacent” to the second component.

As used herein, the term “electro-optical display” is an information display that forms visible images using one or more of electrophoresis, electro-convection, electrochemical interactions, and/or other electrokinetic phenomena.

As used herein, the term “grayscale” applies to both black and white images and monochromatic color images. Grayscale refers to an image including different shades of a single color produced by controlling the density of the single color within a given area of a display.

Embodiments provide electro-optical displays including conductive line, mesh, or lattice electrodes within the display cell. The conductive line, mesh, or lattice electrodes improve the speed, flexibility, and transparency of the electro-optical displays compared to conventional electro-optical displays where transparent conductors are used for the electrodes. In addition, in electro-optical displays utilizing gate electrodes and reservoir electrodes, the conductive line, mesh, or lattice electrodes improve control of the separation between the gate and reservoir electrodes. Further, for dual colorant electro-optical displays, the conductive line, mesh, or lattice electrodes can be arranged in various geometries optimized for electroconvective flow to provide additional independent control of the dual colorants. The conductive line, mesh, or lattice electrodes improve the optical and electrical performance of electro-optical displays, which can be used for electronic skin, electronic paper, and other applications. In one embodiment, the conductive line, mesh, or lattice electrodes are made of metal, silver nanowires, carbon nanotubes, or other suitable conductors. Metal line, mesh, or lattice electrodes can be made of gold, aluminum, nickel, copper, silver, platinum, other suitable metals, alloys thereof, multi-layer structures thereof, or combinations thereof.

In one embodiment, an electrokinetic display, which is based on the combined effect of electrophoretic and electrohydrodynamic forces, includes conductive line, mesh, or lattice electrodes to connect exposed dot regions on a first side of the display and a transparent electrode on the other side of the display. The transparent electrode can be a plate electrode, a patterned electrode, and/or a segmented or pixelated electrode. In the case of a patterned, segmented, or pixelated electrode, the individual segments of the electrode can be addressed individually.

Metal line, mesh, or lattice electrodes use very thin metallic wires. By using very thin metallic wires, the compromise between the transparency and sheet resistance of the conducting materials (e.g., ITO, PEDOT) used for transparent electrodes is eliminated. For larger devices and signage applications, transparent conductors cannot provide a conductivity high enough to allow switching at interactive speeds (i.e., greater than a few tens of milliseconds). Therefore, the optical state of the entire display will not be updated at the same time, which leads to non-uniformity. Conductive line, mesh, and lattice electrodes enable the electrokinetic display architecture to be applied to large format display applications.

The conductive line, mesh, or lattice electrodes improve the transparency of electro-optical displays. The transparency is a function of the clear aperture defined as the area not occupied by conductive wires if the absorption through substrate and dielectric layers of the display is assumed to be negligible. In one embodiment, the line width of the conductive wires can be a few microns or sub-microns to maximize the clear aperture such that the transparency of the display is 90% or better.

In other embodiments, electronic displays including a stack of two electro-optic layers are provided. Each electro-optic layer can include a single colorant or dual colorants for providing a color display. The electronic display including the stack of two electro-optic layers can provide a wide viewing angle (e.g., 180°) and a large clear aperture (e.g., greater than 75%) with negligible parallax issues. This is achieved by separating the active layers of the electronic display by a distance equal to or less than one half the pixel plate size (e.g., 500 μm cell width would have no more than 250 μm of separation between active layers). Structures for both active layers can be formed simultaneously to eliminate alignment issues. By using transparent semiconductors, such as multi-component oxide (MCO) thin film transistors (TFTs) on glass or plastic substrates and by using transparent conductors, such as Indium Tin Oxide (ITO) or poly 3,4-ethylenedioxythiophene (PEDOT) electrodes, transparency of the electronic displays can reach 95%.

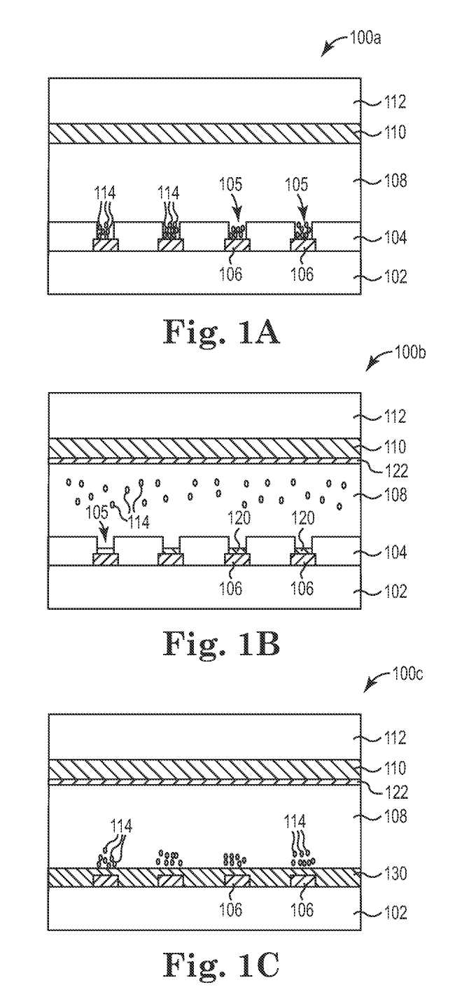

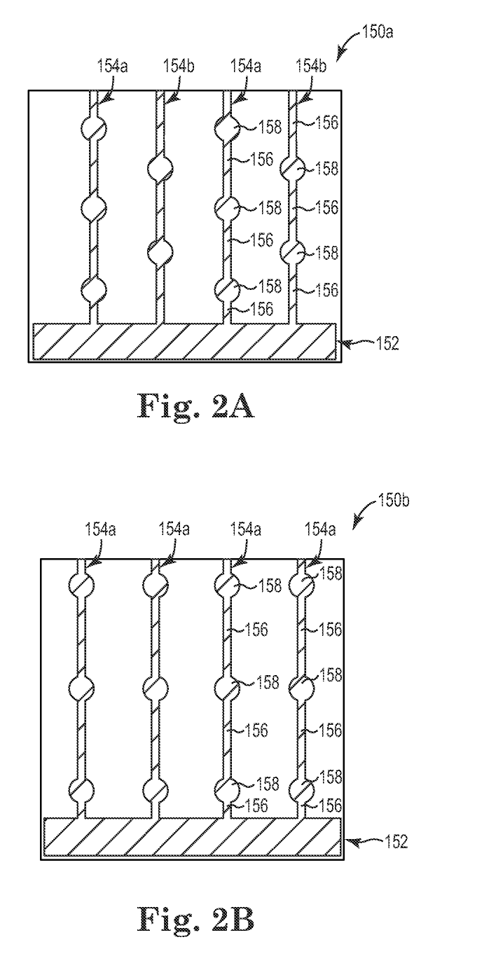

FIG. 1A illustrates a cross-sectional view of one embodiment of an electro-optical display 100a. Electro-optical display 110a includes a first substrate 102, a dielectric layer 104 including recess regions 105, a first electrode 106, a display cell 108, a second electrode 110, and a second substrate 112. Display cell 108 is filled with a carrier fluid with colorant particles 114.

First substrate 102 is parallel to and opposite second substrate 112. In one embodiment, first substrate 102 or second substrate 112 include a reflective material. In another embodiment, first substrate 102 and/or second substrate 112 include an optically clear or transparent material, such as plastic (e.g., polyethylene terephthalate (PET)), glass, or other suitable material. In another embodiment, substrate 102 is coated with or comprises a reflective material. In yet another embodiment, substrate 102 is an opaque material. In still another embodiment, a light scatterer is formed on substrate 102.

First electrode 106 is a reservoir electrode and is parallel to and opposite second electrode 110. First electrode 106 includes segments of a segmented or pixelated conductor formed on substrate 102. First electrode 106 is made from any suitable conductor, such as a metal, silver nanowires, or carbon nanotubes. Second electrode 110 is a continuous, blanket, or solid plate electrode formed on second substrate 112. In other embodiments, second electrode 110 is segmented or pixelated similar to first electrode 106. In one embodiment, second electrode 110 is formed from a film of transparent conductive material. The transparent conductive material can include carbon nanotube layers, a transparent conducting oxide such as ITO (Indium Tin Oxide), or a transparent conducting polymer such as PEDOT (poly 3,4-ethylenedioxythiophene). Other embodiments use other materials that provide suitable conductivity and transparency for electro-optical display 100a. Dielectric layer 104 is formed on substrate 102 and first electrode 106.

Dielectric layer 104 is structured with recess regions 105 that allow charged colorant particles 114 to compact on exposed portions of first electrode 106 in response to a suitable bias being applied to first electrode 106 with respect to second electrode 110.

The carrier fluid within display cell 108 includes either polar fluids (e.g., water) or nonpolar fluids (e.g., dodecane). In other embodiments, anisotropic fluids such as liquid crystal is used. The fluid may include surfactants such as salts, charging agents, stabilizers, and dispersants. In one embodiment, the surfactants provide a fluid that is an electrolyte that is able to sustain current by ionic mass transport. In other embodiments, the fluid may include any suitable medium for enabling fluidic motion of charged particles.

Colorant particles 114 in the carrier fluid are comprised of a charged material in the case of an electrokinetic display. The colorant particle material should be able to hold a stable charge indefinitely so that repeated operation of the display does not affect the charge on the colorant particles. Colorant particle materials having a finite ability to hold a stable charge, however, can be used in accordance with the various embodiments while they maintain their charge. Colorant particles may have a size between several nanometers and several tens of microns and have the property of changing the spectral composition of the incident light by absorbing and/or scattering certain portions of the spectrum. As a result, the particles appear colored, which provides a desired optical effect. In other embodiments, the colorant can be a dye, which is comprised of single absorbing molecules.

Electro-optical display 100a is in a clear optical state. The clear optical state is provided by applying a negative bias to first electrode 106 relative to a reference bias applied to second electrode 110. The negative bias applied to first electrode 106 provides an electrophoretic pull that attracts positively charged colorant particles 114. As a result, colorant particles 114 are compacted on the surface of first electrode 106 within recess regions 105. With colorant particles 114 in clear fluid compacted on the surface of first electrode 106 in recess regions 105, the clear optical state is achieved.

The positively charged colorant particles 114 can be electrophoretically and convectively moved to first electrode 106 and held there by the negative bias applied to first electrode 106 relative to second electrode 110. In one embodiment, the convective flow is a transient effect caused by the ionic mass transport in the carrier fluid, without charge transfer between the carrier fluid and first electrode 106. In this case, the convective flow proceeds for a finite amount of time and facilitates the compaction of colorant particles 114 on first electrode 106 in recess regions 105. After compaction, colorant particles 114 are held on first electrode 106 within recess region 105 by electrostatic forces generated by a coupling with first electrode 106.

In another embodiment, the convective flow is induced by ionic mass transport in the carrier fluid and by charge transfer between the carrier fluid and first electrode 106 and second electrode 110. The charge transfer can occur when the carrier fluid is coupled to the electrodes either through direct contact with the electrodes or separated from the electrodes by an intermediate layer including one or more materials. In the latter case, charge transfer is facilitated by the internal electrical conductivity of the intermediate layer, either volumetric or via pinholes and other defects.

FIG. 1B illustrates a cross-sectional view of another embodiment of an electro-optical display 100b. Electro-optical display 100b is similar to electro-optical display 100a previously described and illustrated with reference to FIG. 1A, except that electro-optical display 100b includes first dielectric passivation layers 120 and second dielectric passivation layer 122. First dielectric passivation layers 120 are self-aligned over first electrode 106 within recess regions 105 of dielectric layer 104. First dielectric passivation layers 120 are formed over first electrode 106 to electrically isolate first electrode 106 from display cell 108. In another embodiment, first dielectric passivation layer 120 can be formed continuously over first electrode 106 and substrate 102. Second dielectric passivation layer 122 is formed over second electrode 110 to electrically isolate second electrode 110 from display cell 108. In another embodiment, second dielectric passivation layer 122 can be excluded. First dielectric passivation layers 120 and/or second dielectric passivation layer 122 may include a reflective dielectric material or an optically clear or transparent dielectric material.

Electro-optical display 100b is in a spread color optical state having the color of colorant particles 114. The spread color optical state is provided by applying pulses or no bias to first electrode 106 relative to the reference bias applied to second electrode 110. The pulses or no bias applied to first electrode 106 spread colorant particles 114 throughout display cell 108. With colorant particles 114 in a clear fluid spread throughout display cell 108, the spread color optical state having the color of colorant particles 114 is achieved.

FIG. 1C illustrates a cross-sectional view of another embodiment of an electro-optical display 100c. Electro-optical display 100c is similar to electro-optical display 100b previously described and illustrated with reference to FIG. 1B, except that in electro-optical display 100c dielectric layer 104 and first dielectric passivation layers 120 are replaced by dielectric passivation layer 130. Dielectric passivation layer 130 is formed over substrate 102 and first electrode 106 to electrically isolate first electrode 106 from display cell 108. Dielectric passivation layer 130 includes a reflective dielectric material or an optically clear or transparent dielectric material. Dielectric passivation layer 130 does not include recess regions for compacting colorant particles over first electrode 106. In other embodiments, dielectric passivation layer 130 may include recess regions for compacting colorant particles over first electrode 106.

Electro-optical display 100c is in the clear optical state. The clear optical state is provided by applying a negative bias to first electrode 106 relative to a reference bias applied to second electrode 110. The negative bias applied to first electrode 106 provides an electrophoretic pull that attracts positively charged colorant particles 114. As a result, colorant particles 114 are compacted on the surface of passivation layer 130 adjacent to first electrode 106. With colorant particles 114 in clear fluid compacted on the surface of passivation layer 103 adjacent to first electrode 106, the clear optical state is achieved.

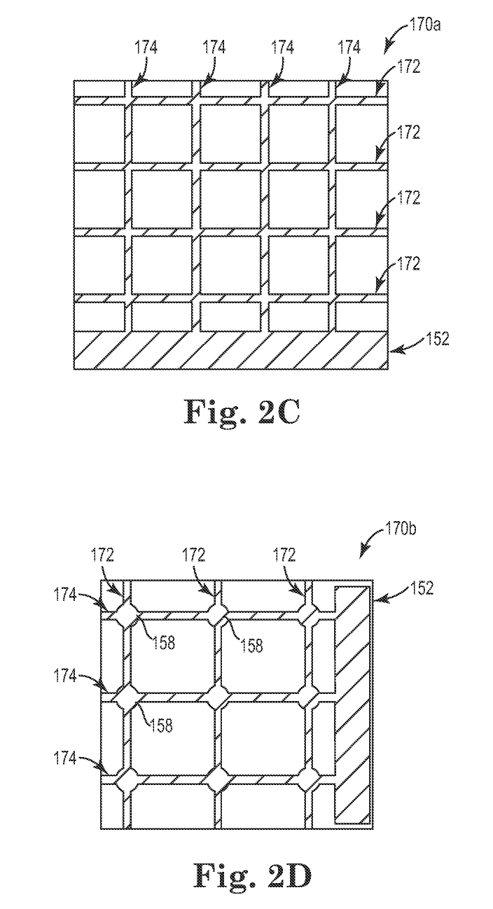

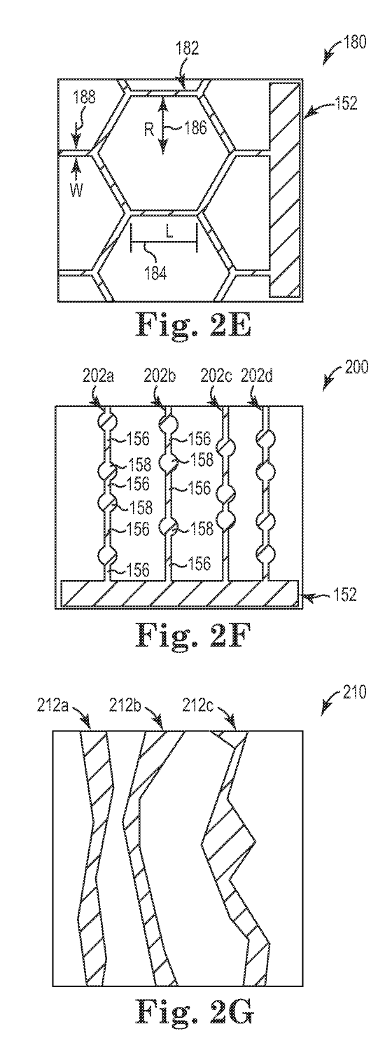

FIG. 2A illustrates a top view of one embodiment of an electrode 150a for an electro-optical display. In one embodiment, electrode 150a is used to provide first electrode 106 previously described and illustrated with reference to FIGS. 1A-1C. Electrode 150a includes a conductive common contact region 152 and conductive lines 154a and 154b coupled to conductive common contact region 152. While a total of four lines 154a and 154b are illustrated in FIG. 2A coupled to common contact region 152, in other embodiments any suitable number of conductive lines can be coupled to common contact region 152.

Each conductive line 154a and 154b includes line regions 156 and dot regions 158. In one embodiment, dot regions 158 having a greater cross-sectional width than line regions 156. Each conductive line 154a and 154b is coupled to common contact region 152 via a line region 156. Each dot region 158 is connected to an adjacent dot region 158 by a line region 156. In one embodiment, each dot region 158 is aligned with a recess region 105 as previously described and illustrated with reference to FIG. 1A. Each line region 156 and common contact region 152 is covered by dielectric layer 104 as previously described and illustrated with reference to FIG. 1A. In the embodiment illustrated in FIG. 2A, dot regions 158 of each conductive line 154a are offset from dot regions 158 of each conductive line 154b. First conductive lines 154a and second conductive lines 154b alternate and are equally spaced from each other.

FIG. 2B illustrates a top view of another embodiment of an electrode 150b for an electro-optical display. In one embodiment, electrode 150b is used to provide first electrode 106 previously described and illustrated with reference to FIGS. 1A-1C. Electrode 150b is similar to electrode 150a previously described and illustrated with reference to FIG. 2A, except that in electrode 150b conductive lines 154b are replaced with conductive lines 154a. Therefore, in this embodiment, dot regions 158 of adjacent conductive lines 154a are aligned.

FIG. 2C illustrates a top view of another embodiment of an electrode 170a for an electro-optical display. In one embodiment, electrode 170a is used to provide first electrode 106 previously described and illustrated with reference to FIGS. 1A-1C. Electrode 170a includes common contact region 152 and a mesh coupled to common contact region 152. The mesh includes first conductive lines 172 and second conductive lines 174. First conductive lines 172 are perpendicular to second conductive lines 174 to provide a mesh pattern. In one embodiment, the intersection of each first conductive line 172 and each second conductive line 174 is aligned with a recess region 105 as previously described and illustrated with reference to FIG. 1A. The remaining portions of first conductive lines 172 and second conductive lines 174 and common contact region 152 are covered by dielectric layer 104 as previously described and illustrated with reference to FIG. 1A.

FIG. 2D illustrates a top view of another embodiment of an electrode 170b for an electro-optical display. In one embodiment, electrode 170b is used to provide first electrode 106 previously described and illustrated with reference to FIGS. 1A-1C. Electrode 170b is similar to electrode 170a previously described and illustrated with reference to FIG. 2C, except that electrode 170b includes a dot region 158 at the intersection between each first conductive line 172 and each second conductive line 174. In one embodiment, each dot region 158 is aligned with a recess region 105 as previously described and illustrated with reference to FIG. 1A.

FIG. 2E illustrates a top view of another embodiment of an electrode 180 for an electro-optical display. In one embodiment, electrode 180 is used to provide first electrode 106 previously described and illustrated with reference to FIG. 1C. Electrode 180 includes a conductive hexagonal lattice structure 182 coupled to common contact region 152.

The relative width and size of conductive hexagonal lattice structure 182 can be optimized to provide a clear aperture. In one embodiment, the width (W) 188 of each line segment is 4.0 μm, the length (L) 184 of each line segment is 73.5 μm, and the radius (R) 186 of each hexagon is 63.7 μm to provide a clear aperture of 94%. In another embodiment, the width (W) 188 of each line segment is 4.0 μm, the length (L) 184 of each line segment is 42.7 μm, and the radius (R) 186 of each hexagon is 37.0 μm to provide a clear aperture of 90%. In yet another embodiment, the width (W) 188 of each line segment is 4.0 μm, the length (L) 184 of each line segment is 29.5 μm, and the radius (R) 186 of each hexagon is 25.5 μm to provide a clear aperture of 86%. In other embodiments, other suitable values for W, L, and R are used to provide the desired clear aperture.

FIG. 2F illustrates a top view of another embodiment of an electrode 200 for an electro-optical display. In one embodiment, electrode 200 is used to provide first electrode 106 previously described and illustrated with reference to FIGS. 1A-1C. Electrode 200 is similar to electrode 150a previously described and illustrated with reference to FIG. 2A, except that in electrode 200 conductive lines 154a and 154b are replaced by conductive lines 202a-202d. In this embodiment, the spacing between conductive lines 202a-202d varies aperiodically and the spacing between each dot region 158 along each conductive line 202a-202d also varies aperiodically.

FIG. 2G illustrates a top view of another embodiment of an electrode 210 for an electro-optical display. In one embodiment, electrode 210 is used to provide first electrode 106 previously described and illustrated with reference to FIGS. 1A-1C. Electrode 210 includes conductive lines 212a-212c. In this embodiment, the spacing between conductive lines 212a-212c varies aperiodically and the shape of each conductive line 212a-212c is distorted.

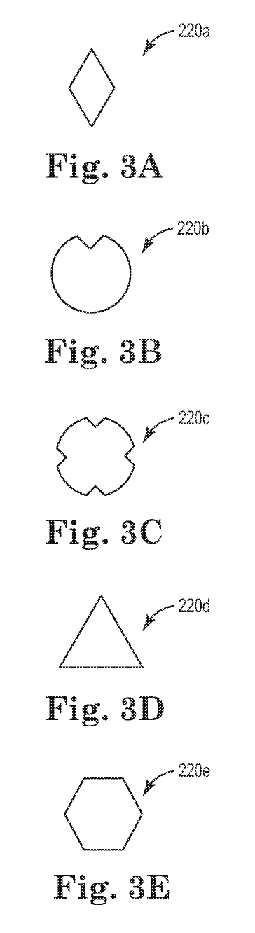

FIG. 3A illustrates a top view of one embodiment of a dot region 220a of an electrode within an electro-optical display. In one embodiment, dot region 220a is used in place of dot region 158 previously described and illustrated with reference to FIGS. 2A, 2B, 2D, and 2F. Dot region 220a is diamond shaped. In one embodiment, recess regions 105 within dielectric layer 104 previously described and illustrated with reference to FIG. 1A also have the same shape as dot region 220a.

FIG. 3B illustrates a top view of another embodiment of a dot region 220b of an electrode within an electro-optical display. In one embodiment, dot region 220b is used in place of dot region 158 previously described and illustrated with reference to FIGS. 2A, 2B, 2D, and 2F. Dot region 220b is circular shaped with a single triangular portion removed. In one embodiment, recess regions 105 within dielectric layer 104 previously described and illustrated with reference to FIG. 1A also have the same shape as dot region 220b.

FIG. 3C illustrates a top view of another embodiment of a dot region 220c of an electrode within an electro-optical display. In one embodiment, dot region 220c is used in place of dot region 158 previously described and illustrated with reference to FIGS. 2A, 2B, 2D, and 2F. Dot region 220c is circular shaped with a four triangular portions removed. The removed triangular portions are equally spaced around dot region 220c. In one embodiment, recess regions 105 within dielectric layer 104 previously described and illustrated with reference to FIG. 1A also have the same shape as dot region 220c.

FIG. 3D illustrates a top view of another embodiment of a dot region 220d of an electrode within an electro-optical display. In one embodiment, dot region 220d is used in place of dot region 158 previously described and illustrated with reference to FIGS. 2A, 2B, 2D, and 2F. Dot region 220d is triangular shaped. In one embodiment, recess regions 105 within dielectric layer 104 previously described and illustrated with reference to FIG. 1A also have the same shape as dot region 220d.

FIG. 3E illustrates a top view of another embodiment of a dot region 220e of an electrode within an electro-optical display. In one embodiment, dot region 220e is used in place of dot region 158 previously described and illustrated with reference to FIGS. 2A, 2B, 2D, and 2F. Dot region 220e is hexagon shaped. In one embodiment, recess regions 105 within dielectric layer 104 previously described and illustrated with reference to FIG. 1A also have the same shape as dot region 220e.

While FIGS. 3A-3E illustrate five embodiments of a dot region of an electrode within an electro-optical display, in other embodiments other suitable shaped dot regions are used.

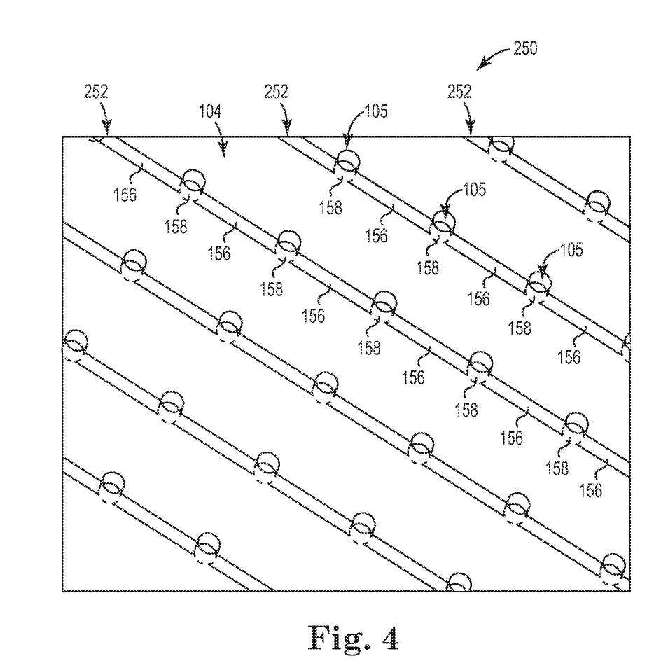

FIG. 4 illustrates a view of a portion 250 of one embodiment of an electro-optical display. Portion 250 includes conductive lines 252 and dielectric layer 104. In one embodiment, conductive lines 252 provide first electrode 106 previously described and illustrated with reference to FIG. 1A. Each conductive line 252 includes dot regions 158 connected by line regions 156. Recess regions 105 are circular in shape and are formed in dielectric layer 104 to expose dot regions 158 of conductive lines 252. Recess regions 105 provide reservoir regions for colorant particles to compact in response to a suitable bias being applied to conductive lines 252. In other embodiments, dot regions 158 and recess regions 105 can have other suitable shapes, such as the shapes previously described and illustrated with reference to FIGS. 3A-3E.

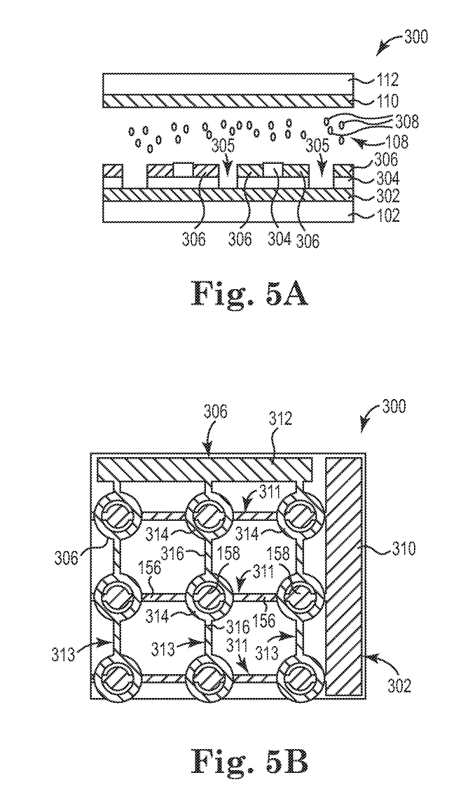

FIG. 5A illustrates a cross-sectional view and FIG. 5B illustrates a top view of another embodiment of an electro-optical display 300. Electro-optical display 300 includes a first substrate 102, a first electrode 302, a dielectric layer 304 including recess regions 305, a display cell 108, a gate electrode 306, a second electrode 110, and a second substrate 112. Display cell 108 is filled with a carrier fluid with colorant particles 308. Gate electrode 306 is adjacent to the top of recess regions 305.

First electrode 302 is a reservoir electrode and includes a conductive common contact region 310 and conductive lines 311 coupled to common contact region 310. Conductive lines 311 include dot regions 158 and line regions 156 between dot regions 158. Gate electrode 306 includes a conductive common contact region 312 and conductive lines 313 coupled to common contact region 312. Conductive lines 313 include ring regions 314 and line regions 316 between ring regions 314. Each ring region 314 of gate electrode 306 surrounds a recess region 305 and is aligned with a dot region 158 of first electrode 302. In one embodiment, first electrode 302 and gate electrode 306 are made from the same conductive material. In one embodiment, first electrode 302 and gate electrode 306 are passivated by a dielectric passivation layer to electrically isolate first electrode 302 and gate electrode 306 from display cell 108.

Gate electrode 306 is used to control the movement of colorant particles 308 into and out of recess regions 305. Gate electrode 306 is used to control an amount of the colorant particles 308 released from recess regions 305 and moved into the wider portions of display cell 108. By controlling the amount of colorant particles 308 released from recess regions 305 of display cell 108 and moved into the wider portion of display cell 108, gate electrode 306 also controls the color perceived by a viewer of electro-optical display 300, including a variety of tones in the grayscale.

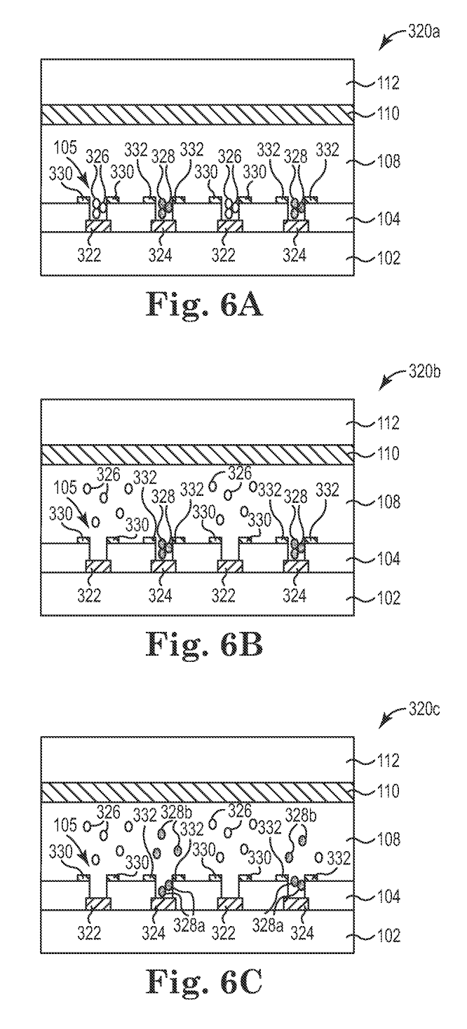

FIG. 6A illustrates a cross-sectional view of one embodiment of an electro-optical display 320a in a clear optical state. Electro-optical display 320a includes a first substrate 102, first electrodes 322 and 324, a dielectric layer 104 including recess regions 105, a display cell 108, gate electrodes 330 and 332, a second electrode 110, and a second substrate 112. Gate electrode 330 surround recess regions 105 above first electrode 322 and gate electrode 332 surround recess regions 105 above first electrode 324. Display cell 320a is filled with a carrier fluid with dual colorant ink including charged colorant particles 326 and 328.

Charged colorant particles 326 and 328 in dual colorant ink are oppositely charged and each provides a different color, such as cyan and magenta. Colorants in dual colorant ink can be any combination of primary subtractive or additive colorants, such as cyan, magenta, yellow, black, red, green, blue, and white. First electrode 322 and gate electrode 330 are used to control the movement of colorant particles 326, and first electrode 324 and gate electrode 332 are used to control the movement of colorant particles 328.

In the clear optical state, a positive bias is applied to first electrode 322, a negative bias is applied to first electrode 324, and no bias is applied to gate electrodes 330 and 332 relative to a reference bias applied to second electrode 110. The positive bias applied to first electrode 322 attracts negatively charged colorant particles 326 to compact on the surface of first electrode 322. The negative bias applied to first electrode 324 attracts positively charged colorant particles 328 to compact on the surface of first electrode 324. With colorant particles 326 and 328 compacted in recess regions 105, the clear optical state is achieved.

FIG. 6B illustrates a cross-sectional view of one embodiment of an electro-optical display 320b in a first color optical state. In the first color optical state, a negative bias is applied to first electrodes 322 and 324, a positive bias is applied to gate electrode 330, and no bias is applied to gate electrode 332 relative to a reference bias applied to second electrode 110. The negative bias applied to first electrode 322 and the positive bias applied to gate electrode 330 releases all negatively charged colorant particles 326 from recess regions 105 such that colorant particles 326 are spread within display cell 108. The negative bias applied to first electrode 324 attracts positively charged colorant particles 328 to compact on the surface of first electrode 324. With colorant particles 326 spread in display cell 108 and colorant particles 328 compacted in recess regions 105, the first color optical state having the color of colorant particles 326 is achieved.

FIG. 6C illustrates a cross-sectional view of one embodiment of an electro-optical display 320c in a second color optical state. In the second color optical state, a negative bias is applied to first electrodes 322 and 324, a positive bias is applied to gate electrode 330, and a negative bias is applied to gate electrode 332 relative to a reference bias applied to second electrode 110. The negative bias applied to first electrode 322 and the positive bias applied to gate electrode 330 releases all positively charged colorant particles 326 from recess regions 105 such that colorant particles 326 are spread within display cell 108.

The negative bias applied to first electrode 324 and the negative bias applied to gate electrode 332 repel negatively charged colorant particles 328. Based on the negative bias applied to first electrode 324 and on the negative bias applied to gate electrode 332, the amount of colorant particles 328 released from recess regions 105 of display cell 108 adjacent to first electrode 324 can be controlled. As a result, some of colorant particles 328 remain in the recess regions 105 as indicated by colorant particles 328a and some of colorant particles 328 pass to the wider portion of display cell 108 as indicated by colorant particles 328b. With colorant particles 326 and 328b spread in display cell 108 and colorant particles 328a compacted in recess regions 105, the second color optical state having a color based on the combination of colorant particles 326 and 328b is achieved. In other embodiments, other color optical states can be achieved by controlling the amount of colorant particles 326 and 328 released from recess regions 105.

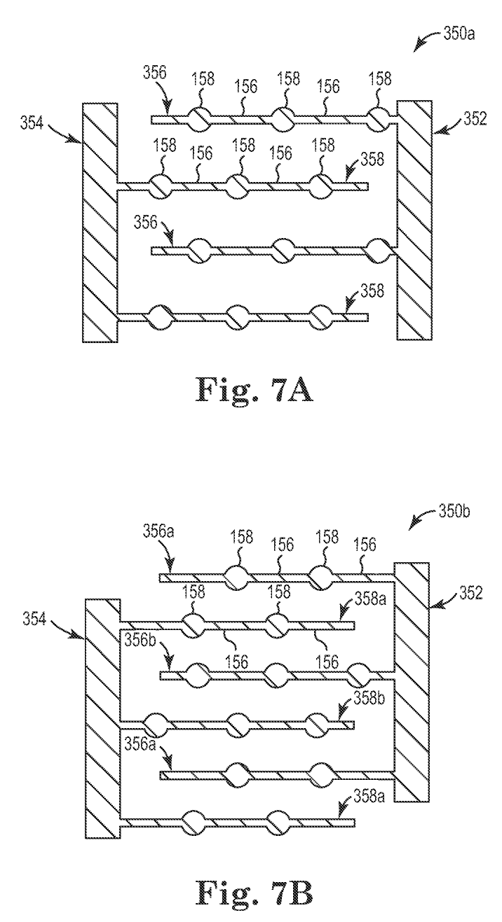

FIG. 7A illustrates a top view of one embodiment of electrodes 350a for a dual color electro-optical display. In one embodiment, electrodes 350a provide first electrodes 322 and 324 previously described and illustrated with reference to FIG. 6A. Electrodes 350a include conductive lines 356 coupled to a conductive common contact region 352 and conductive lines 358 coupled to a conductive common contact region 354. Each conductive line 356 and 358 includes dot regions 158 and line regions 156 between dot regions 158. In other embodiments, dot regions 158 are excluded. Common contact region 352 is parallel to and opposite to common contact region 354. Conductive lines 356 and 358 are interdigitated. Dot regions 158 of adjacent conductive lines 356 are aligned. Dot regions 158 of adjacent conductive lines 358 are aligned. Dot regions 158 of conductive lines 356 are offset from dot regions 158 of conductive lines 358. Common contact region 352 and conductive lines 356 are used to control the movement of one colorant and common contact region 354 and conductive lines 358 are used to control the movement of another colorant in a dual color electro-optical display.

FIG. 7B illustrates a top view of another embodiment of electrodes 350b for a dual color electro-optical display. In one embodiment, electrodes 350b provide first electrodes 322 and 324 previously described and illustrated with reference to FIG. 6A. Electrodes 350b are similar to electrodes 350a previously described and illustrated with reference to FIG. 7A, except that electrodes 350b includes conductive lines 356a and 356b and conductive lines 358a and 358b.

Conductive lines 356a and 356b are coupled to common contact region 352. Dot regions 158 of conductive lines 356a are offset from dot regions 158 of conductive lines 356b. Conductive lines 358a and 358b are coupled to common contact region 354. Dot regions 158 of conductive lines 358a are offset from dot regions 158 of conductive lines 358b. Dot regions 158 of each conductive line 356a are aligned with dot regions 158 of each adjacent conductive line 358b. Dot regions 158 of each conductive line 356b are aligned with dot regions 158 of each adjacent conductive line 358a. Common contact region 352 and conductive lines 356a and 356b are used to control the movement of one colorant and common contact region 354 and conductive lines 358a and 358b are used to control the movement of another colorant in a dual color electro-optical display.

While FIGS. 7A and 7B illustrate specific combinations of interdigitated lines including dot regions and line regions, in other embodiments other suitable combinations can be provided to control the movement of colorants in a dual color electro-optical display.

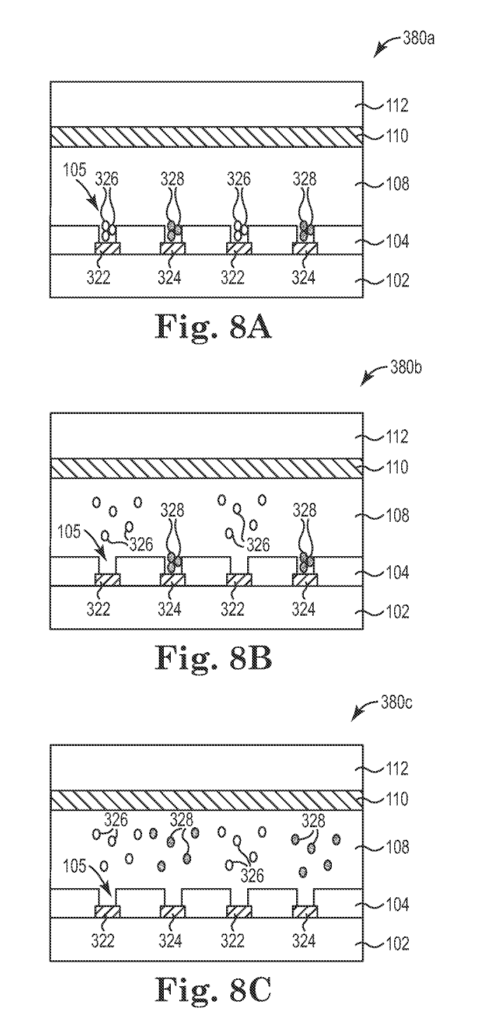

FIG. 8A illustrates a cross-sectional view of one embodiment of an electro-optical display 380a in a clear optical state. Electro-optical display 380a includes a first substrate 102, a dielectric layer 104 including recess regions 105, first electrodes 322 and 324, a display cell 108, a second electrode 110, and a second substrate 112. Display cell 108 is filled with a carrier fluid with colorant particles 326 and 328. Charged colorant particles 326 and 328 in dual colorant ink are oppositely charged and each provides a different color, such as cyan and magenta. First electrode 322 is used to control the movement of colorant particles 326, and first electrode 324 is used to control the movement of colorant particles 328.

In the clear optical state, a positive bias is applied to first electrode 322 and a negative bias is applied to first electrode 324 relative to a reference bias applied to second electrode 110. The positive bias applied to first electrode 322 attracts negatively charged colorant particles 326 to compact on the surface of first electrode 322. The negative bias applied to first electrode 324 attracts positively charged colorant particles 328 to compact on the surface of first electrode 324. With colorant particles 326 and 328 compacted in recess regions 105, the clear optical state is achieved.

FIG. 8B illustrates a cross-sectional view of one embodiment of an electro-optical display 380b in a first color optical state. In the first color optical state, pulses are applied to first electrode 322 and a negative bias is applied to first electrode 324 relative to a reference bias applied to second electrode 110. The pulses applied to first electrode 322 spread negatively charged colorant particles 326 within display cell 108. The amount of spreading of colorant particles 326 is controlled based on the pulses to provide a desired grayscale for colorant particles 326. The negative bias applied to first electrode 324 attracts positively charged colorant particles 328 to compact on the surface of first electrode 324. With colorant particles 326 spread in display cell 108 and colorant particles 328 compacted in recess regions 105, the first color optical state having the color of colorant particles 326 is achieved.

FIG. 8C illustrates a cross-sectional view of one embodiment of an electro-optical display 380c in a second color optical state. In the second color optical state, pulses are applied to first electrode 322 and first electrode 324 relative to a reference bias applied to second electrode 110. The pulses applied to first electrode 322 spread negatively charged colorant particles 326 within display cell 108. The amount of spreading of colorant particles 326 is controlled based on the pulses to provide a desired grayscale for colorant particles 326. The pulses applied to first electrode 324 spread positively charged colorant particles 328 within display cell 108. The amount of spreading of colorant particles 328 is controlled based on the pulses to provide a desired grayscale for colorant particles 328. With colorant particles 326 and 328 spread in display cell 108, the second color optical state having the color of a combination of colorant particles 326 and 328 is achieved.

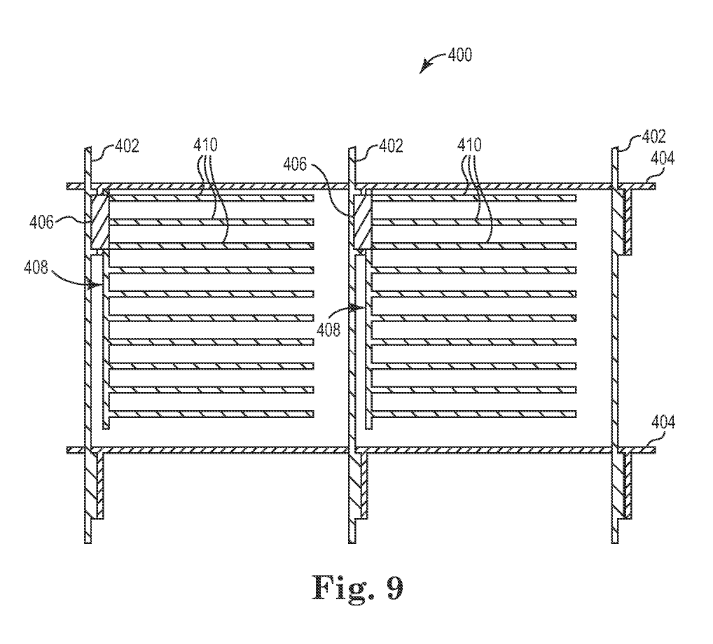

FIG. 9 illustrates a top view of one embodiment of a pixelated electro-optical display 400. Electro-optical display 400 is a single color per pixel display. Electro-optical display 400 includes data lines 402, control lines 404, transistors or switches 406, and electrodes 408. In one embodiment, data lines 402 and control lines 404 are conductive lines. In one embodiment, transistors or switches 406 are thin film transistors.

Each electrode 408 includes a plurality of conductive lines 410 to provide one pixel of electro-optical display 400. While two pixels are illustrated in FIG. 9, electro-optical display 400 can include any suitable number of pixels including any suitable number of rows of pixels and any suitable number of columns of pixels. In one embodiment, conductive lines 410 provide first electrode 106 previously described and illustrated with reference to FIGS. 1A-1C. Each electrode 408 is individually activated through a respective transistor or switch 406 based on signals applied to data lines 402 and control lines 404. In this way, each individual pixel of electro-optical display 400 can be controlled to provide a desired image.

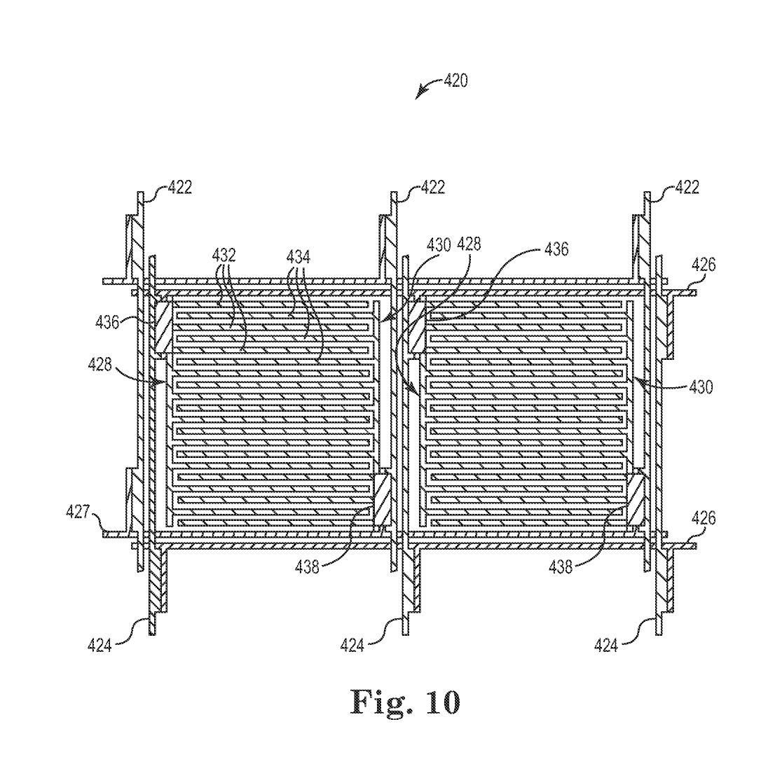

FIG. 10 illustrates a top view of another embodiment of a pixelated electro-optical display 420. Electro-optical display 420 is a dual color per pixel display. Electro-optical display 420 includes first color data lines 424, second color data lines 422, first color control lines 426, second color control lines 427, transistors or switches 436 and 438, first color electrodes 428, and second color electrodes 430. In one embodiment, data lines 424 and 422 and control lines 426 and 427 are conductive lines. In one embodiment, transistors or switches 436 and 438 are thin film transistors.

Each first color electrode 428 includes a plurality of conductive lines 432 for controlling the movement of one colorant of each pixel of electro-optical display 400. Each second color electrode 430 includes a plurality of conductive lines 434 to control the movement of another colorant of each pixel of electro-optical display 400. Conductive lines 432 and conductive lines 434 are interdigitated. In one embodiment, conductive lines 432 provide first electrode 322 and conductive lines 434 provide first electrode 324 previously described and illustrated with reference to FIGS. 8A-8C.

Each electrode 428 is individually activated through a respective transistor or switch 436 based on signals applied to data lines 424 and control lines 426. Each electrode 430 is individually activated through a respective transistor or switch 438 based on signals applied to data lines 422 and control lines 427. In this way, each individual colorant of each individual pixel of electro-optical display 420 can be controlled to provide a desired image.

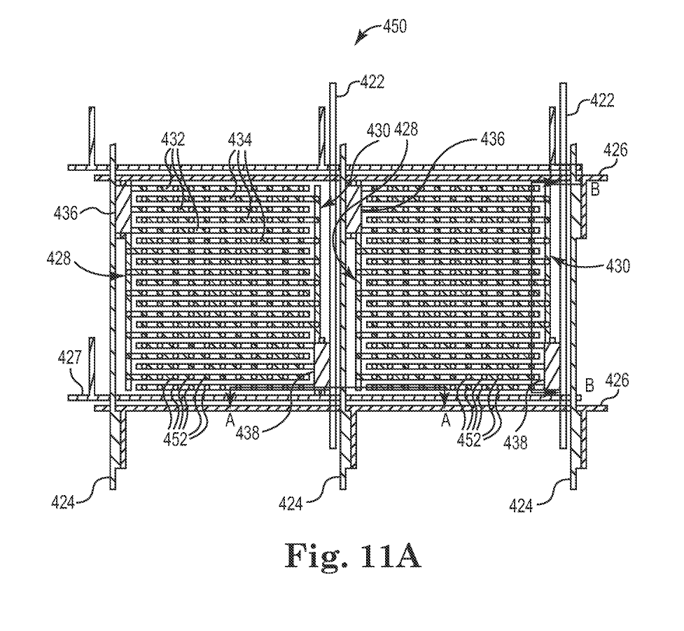

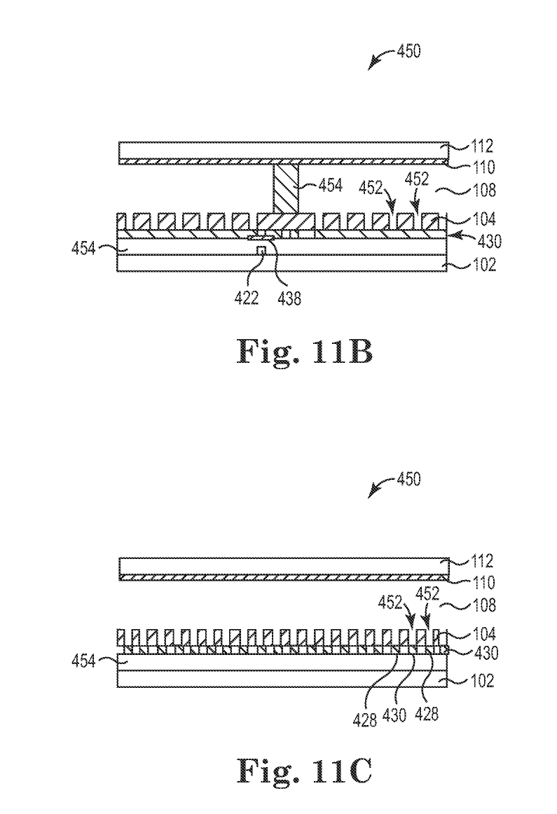

FIG. 11A illustrates a top view of one embodiment of a pixelated electro-optical display 450. FIG. 11B illustrates a first cross-sectional view of pixelated electro-optical display 450 illustrated in FIG. 11A taken along A-A. FIG. 11C illustrates a second cross-sectional view of pixelated electro-optical display 450 illustrated in FIG. 11A taken along B-B. Electro-optical display 450 is similar to electro-optical display 420 previously described and illustrated with reference to FIG. 10, except that electro-optical display 450 includes dot regions 452 along conductive lines 432 and 434.

As illustrated in FIGS. 11B and 11C, electro-optical display 450 also includes a first substrate 102, a dielectric layer 454, a dielectric layer 104 including recess regions 452 for the dot regions, dielectric containment walls 454, top electrode 110, a second substrate 112, and display cells 108. Each display cell 108 between containment walls 454 includes a carrier fluid with dual colorant particles to define each pixel of electro-optical display 450. Electro-optical display 450 operates similarly to electro-optical display 420 previously described and illustrated with reference to FIG. 10.

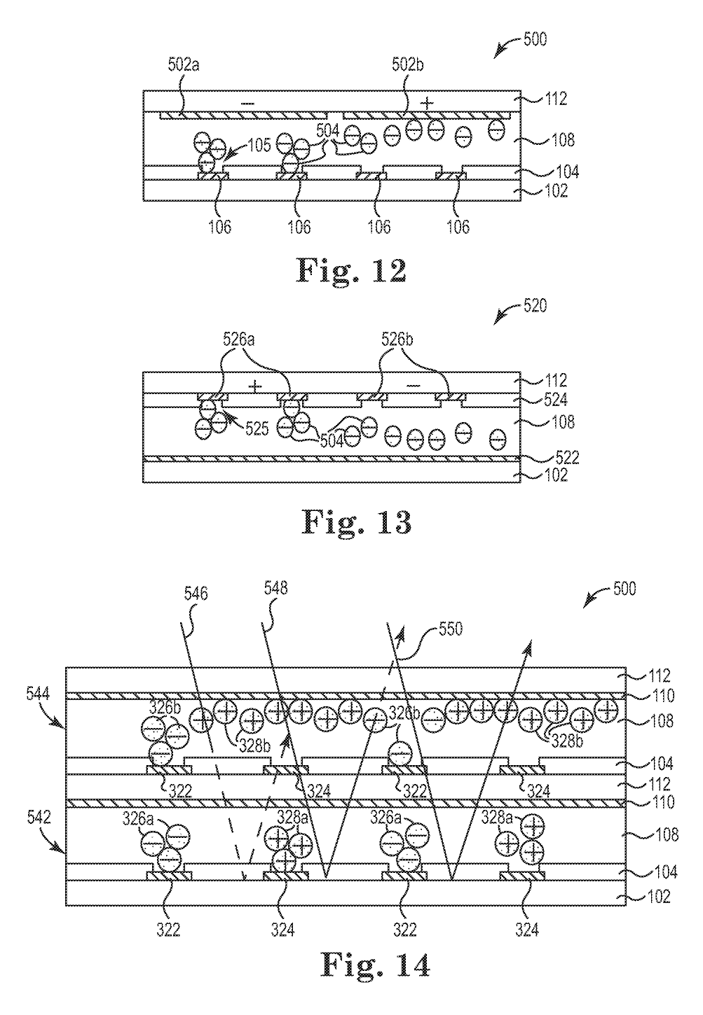

FIG. 12 illustrates a cross-sectional view of another embodiment of an electro-optical display 500. Electro-optical display 500 includes a first substrate 102, a first electrode 106, dielectric material 104 with recess regions 105, a display cell 108, second electrodes 502a and 502b, and a second substrate 112. Display cell 108 is filled with a carrier fluid with negatively charged colorant particles 504. First electrode 106 includes conductive lines, a conductive mesh, or a conductive lattice and second electrodes 502a and 502b are blanket or plate transparent conductors. In this embodiment, a reference bias is applied to first electrode 106 and each second electrode 502a and 502b is individually controlled for controlling the movement of colorant particles 504.

To provide a clear optical state as illustrated in a portion of display cell 108, a negative bias is applied to second electrode 502a relative to the reference bias applied to first electrode 106. With the negative bias applied to second electrode 502a relative to the reference bias applied to first electrode 106, negatively charged colorant particles 504 are attracted by first electrode 106 to compact in recess regions 105. To provide a spread optical state as illustrated in another portion of display cell 108, a positive bias is applied to second electrode 502b relative to the reference bias applied to first electrode 106. With the positive bias applied to second electrode 502b relative to the reference bias applied to first electrode 106, negatively charged colorant particles 504 are attracted by second electrode 502b and are spread over second electrode 502b.

FIG. 13 illustrates a cross-sectional view of another embodiment of an electro-optical display 520. Electro-optical display 520 includes a first substrate 102, a first electrode 522, dielectric material 524 with recess regions 525, a display cell 108, second electrodes 526a and 526b, and a second substrate 112. Display cell 108 is filled with a carrier fluid with negatively charged colorant particles 504. First electrode 522 is a blanket transparent conductor and second electrodes 526a and 526b include conductive lines, a conductive mesh, or a conductive lattice. In this embodiment, a reference bias is applied to first electrode 522 and each second electrode 526a and 526b is individually controlled for controlling the movement of colorant particles 504.

To provide a clear optical state as illustrated in a portion of display cell 108, a positive bias is applied to second electrode 526a relative to the reference bias applied to first electrode 522. With the positive bias applied to second electrode 526a relative to the reference bias applied to first electrode 522, negatively charged colorant particles 504 are attracted by second electrode 526a to compact in recess regions 525. To provide a spread optical state as illustrated in another portion of display cell 108, a negative bias is applied to second electrode 526b relative to the reference bias applied to first electrode 522. With the negative bias applied to second electrode 526b relative to the reference bias applied to first electrode 522, negatively charged colorant particles 504 are attracted by first electrode 522 and are spread in display cell 108 between first electrode 522 and second electrode 526b.

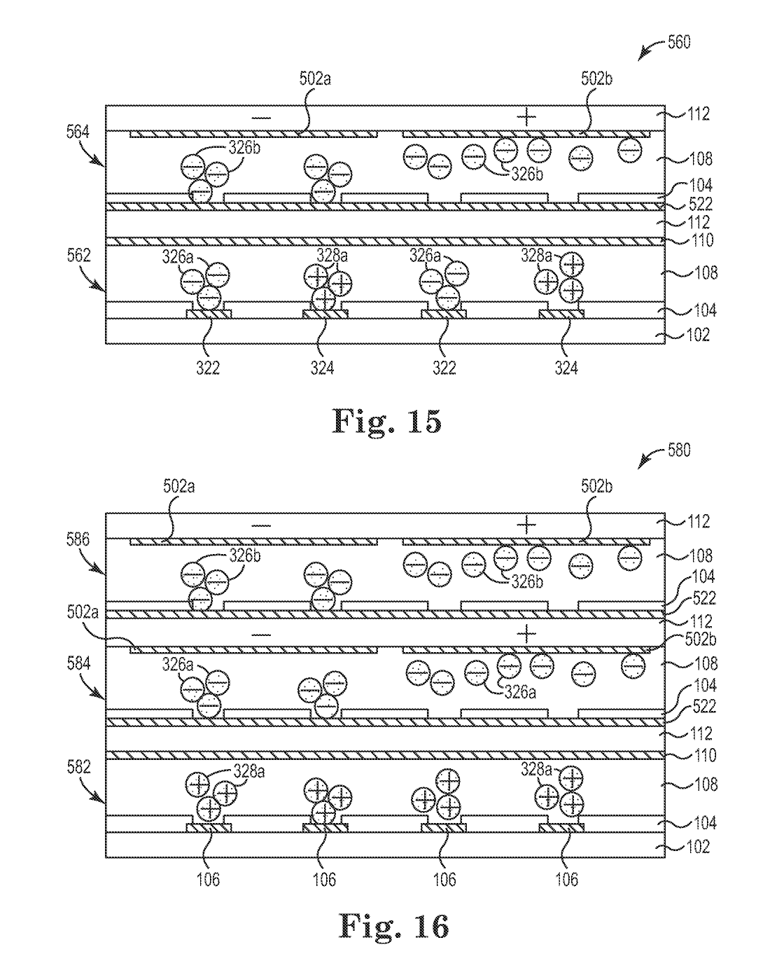

FIG. 14 illustrates a cross-sectional view of one embodiment of a full color electro-optical display 540. Electro-optical display 540 includes a dual layer stack including display element layers 542 and 544. Each layer 542 and 544 is similar to electro-optical display 380a previously described and illustrated with reference to FIG. 8A. Layer 542 includes a first dual colorant ink (e.g., magenta and black), and layer 544 includes a second dual colorant ink (e.g., cyan and yellow). In this embodiment, first substrate 102 is reflective or includes a reflective layer. In one embodiment, the reflective layer is white. The bias applied to first electrodes 322 and 324 of first layer 542 and second layer 544 can be individually controlled as previously described and illustrated with reference to FIGS. 8A-8C. By controlling the bias applied to the electrodes, the movement of the first and second dual colorant inks of electro-optical display 540 can be controlled to display desired colors as indicated at 546, 548, and 550.

FIG. 15 illustrates a cross-sectional view of another embodiment of a full color electro-optical display 560. Electro-optical display 560 includes a dual layer stack including display element layers 562 and 564. Layer 562 is similar to electro-optical display 308a previously described and illustrated with reference to FIG. 8A. Layer 564 is similar to electro-optical display 500 previously described and illustrated with reference to FIG. 12, except that in layer 564 first electrode 106 is replaced by first electrode 522. First electrode 522 is a blanket transparent conductor.

Layer 562 includes a dual colorant ink (e.g., magenta and cyan), and layer 564 includes a single colorant ink (e.g., yellow). In this embodiment, first substrate 102 is reflective or includes a reflective layer. In one embodiment, the reflective layer is white. The bias applied to first electrodes 322 and 324 of first layer 542 and to second electrodes 502a and 502b of second layer 564 can be individually controlled as previously described and illustrated with reference to FIGS. 8A-8C and 12, respectively. By controlling the bias applied to the electrodes, the movement of the dual colorant ink and the single colorant ink of electro-optical display 560 can be controlled to display desired colors.

FIG. 16 illustrates a cross-sectional view of another embodiment of a full color electro-optical display 580. Electro-optical display 580 includes a three layer stack including display element layers 582, 584, and 586. Layer 582 is similar to electro-optical display 100a previously described and illustrated with reference to FIG. 1A. Layers 584 and 586 are similar to electro-optical display 500 previously described and illustrated with reference to FIG. 12, except that in layers 584 and 586 first electrode 106 is replaced by first electrode 522. First electrode 522 is a blanket transparent conductor.

Layer 582 includes a single colorant ink (e.g., magenta), layer 584 includes a single colorant ink (e.g., cyan), and layer 586 includes a single colorant ink (e.g., yellow). In this embodiment, first substrate 102 is reflective or includes a reflective layer. In one embodiment, the reflective layer is white. The bias applied to first electrode 106 of layer 582 and to second electrodes 502a and 502b of layers 584 and 586 can be individually controlled as previously described and illustrated with reference to FIGS. 1A and 12, respectively. By controlling the bias applied to the electrodes, the movement of the single colorant ink within each layer of electro-optical display 580 can be controlled to display desired colors.

By using conductive lines, meshes, or lattices in electro-optical displays, the flexibility and robustness of the electrode layer is improved, which increases the overall display reliability. In addition, using conductive lines for gate electrodes can reduce shorting between the gate and reservoir electrodes since the gate electrode can be defined around the reservoir openings. Line electrodes also enable independent control of dual colorant inks by utilizing exposed dots on separate line electrodes. The exposed dots can be arranged in regular patterns that are optimized for the given spacial frequency of electro-convection to provide optimal switching and compaction for both colorants.

Further, by using conductive lines, meshes, or lattices in place of blanket transparent electrodes, the substrate can be index matched to the dielectric layer. Typically, the index of electronic ink is relatively close to that of the substrate so that the addition of a transparent electrode introduces an index discontinuity, which can contribute to optical loss. Since optical loss increases as the number of transparent electrode layers increases in a stacked architecture, the use of conductive lines, meshes, or lattices in place of transparent electrode layers removes this constraint in the overall design. Therefore, the conductive line, mesh, or lattice electrodes enhance the overall performance of the electro-optical display, thus enabling a highly performing stacked architecture.

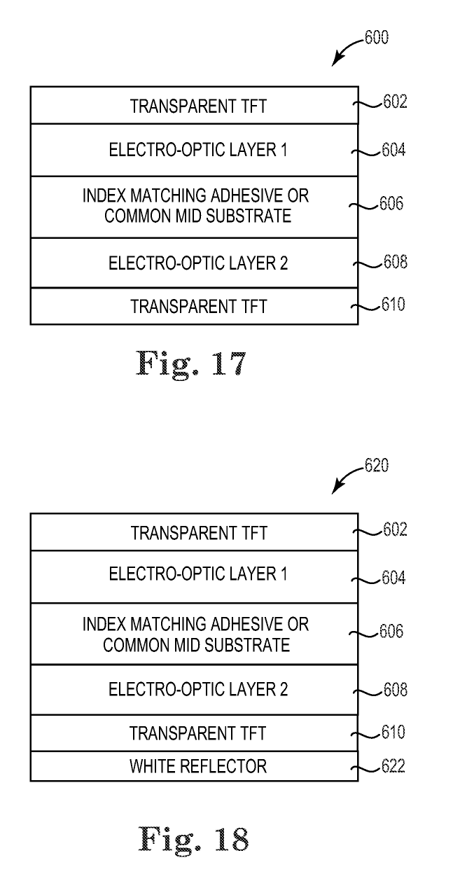

FIG. 17 illustrates one embodiment of an electronic display 600 including two electro-optic layers. Electronic display 600 includes a transparent thin film transistor (TFT) layer 602, a first electro-optic layer 604, an index matching adhesive layer or a common mid substrate 606, a second electro-optic layer 608, and a transparent TFT layer 610. In one embodiment, first electro-optic layer 604 includes a lower substrate and second electro-optic layer 608 includes an upper substrate, and the two substrates are bonded together via index matching adhesive layer 606. In another embodiment, first electro-optic layer 604 and second electro-optic layer 608 share a common mid substrate 606. Second electro-optic layer 608 is arranged on transparent TFT layer 610. Index matching adhesive layer or common mid substrate 606 is arranged between second electro-optic layer 608 and first electro-optic layer 604. Transparent TFT layer 602 is arranged on first electro-optic layer 604.

In one embodiment, layer 606 is a layer of index matching adhesive bonding first electro-optic layer 604 to second electro-optic layer 608. In this embodiment, first electro-optic layer 604 and transparent TFT layer 602 can be fabricated separately from second electro-optic layer 608 and transparent TFT layer 610. By fabricating first electro-optic layer 604 and transparent TFT layer 602 separate from second electro-optic layer 608 and transparent TFT layer 610, the fabrication process of first electro-optic layer 604 and transparent TFT layer 602 and second electro-optic layer 608 and transparent TFT layer 610 may be simplified. In addition, each of the electro-optic layers can be individually tested prior to bonding. After each electro-optic layer has been tested, an optical adhesive or other suitable adhesive is applied to first electro-optic layer 604 and/or to second electro-optic layer 608. First electro-optic layer 604 is optically aligned with the second electro-optic layer 608 such that each pixel of first electro-optic layer 604 is aligned with a pixel of second electro-optic layer 608. The optical adhesive is then cured using ultraviolet (UV) light or thermal or other suitable method to bond the aligned electro-optic layers to each other.

In another embodiment, layer 606 is a common mid substrate. In this embodiment, the lower portion of first electro-optic layer 604 is fabricated on the top surface of the common mid substrate, and the upper portion of second electro-optic layer 608 is fabricated on the bottom surface of the common mid substrate. In this embodiment, the distance between first electro-optic layer 604 and second electro-optic layer 608 can be reduced compared to the embodiment in which the index matching adhesive is used. In addition, embossing or other suitable processes can be used during the fabrication process to align each pixel of first electro-optic layer 604 with a pixel of second electro-optic layer 608.

Electronic display 600 is a transparent display including a dual layer stack that provides print-like color. Transparent TFT layer 602 includes a transparent substrate and TFTs. In one embodiment, transparent TFT layer 602 also includes transparent capacitors for driving first electro-optic layer 604. The TFTs in layer 602 are electrically coupled to electrodes in the upper portion of first electro-optic layer 604 to modulate one or two primary colorants within first electro-optic layer 604. The one or two primary colorants within the first electro-optic layer 604 can be modulated using electrophoretics and/or electrokinetics to provide a colored optical state or a transparent optic state for first electro-optic layer 604.

Likewise, transparent TFT layer 610 includes a transparent substrate and TFTs. In one embodiment, transparent TFT layer 610 also includes transparent capacitors for driving second electro-optic layer 608. The TFTs in layer 610 are electrically coupled to electrodes in the lower portion of second electro-optic layer 608 to modulate one or two primary colorants within second electro-optic layer 608. The one or two primary colorants within the second electro-optic layer 608 can be modulated using electrophoretics and/or electrokinetics to provide a colored optical state or a transparent optic state for second electro-optic layer 608.

In one embodiment, first electro-optic layer 604 and/or second electro-optic layer 608 each include an electro-optical display similar to the electro-optical display previously described and illustrated with reference to FIGS. 1A-1C. In another embodiment, first electro-optic layer 604 and/or second electro-optic layer 608 each include an electro-optical display similar to the electro-optical display previously described and illustrated with reference to FIGS. 1A-1C except that electrode 106 is made of a transparent conductive material, such as ITO or PEDOT.

In another embodiment, first electro-optic layer 604 and/or second electro-optic layer 608 each include an electro-optical display similar to the electro-optical display previously described and illustrated with reference to FIGS. 8A-8C. In another embodiment, first electro-optic layer 604 and/or second electro-optic layer 608 each include an electro-optical display similar to the electro-optical display previously described and illustrated with reference to FIGS. 8A-8C except that electrodes 322 and 324 are made of a transparent conductive material, such as ITO or PEDOT.

In another embodiment, first electro-optic layer 604 and/or second electro-optic layer 608 each include an electro-optical display similar to the electro-optical display previously described and illustrated with reference to FIG. 12. In yet another embodiment, first electro-optic layer 604 and/or second electro-optic layer 608 each include an electro-optical display similar to the electro-optical display previously described and illustrated with reference to FIG. 13. In other embodiments, first electro-optic layer 604 and second electro-optic layer 608 include other suitable electro-optical displays capable of modulating one or two primary colorants within each electro-optic layer using electrophoretics and/or electrokinetics.

Combinations of single and/or dual colorants in each electro-optic layer 604 and 608 can provide a white optical state (i.e., all layers clear), a colored optical state (i.e., independent modulation of colorants in each layer), and a dark optical state (i.e., all layers colored). In one embodiment, combinations of subtractive colorants including cyan, magenta, and yellow (CMY) or cyan, magenta, yellow, and black (CMYK) are used for the single and/or dual colorants in each electro-optic layer. In another embodiment, combinations of additive colorants including red, green, and blue (RGB) or red, green, blue, and white (RGBW) are used for the single and/or dual colorants in each electro-optic layer. In other embodiments, a hybrid of subtractive and additive colorants are used such that one electro-optic layer uses subtractive colorants while the other electro-optic layer uses additive colorants. In yet other embodiments, each electro-optic layer can use a combination of additive and subtractive colorants.

For example, in one embodiment first electro-optic layer 604 includes a single yellow colorant, and second electro-optic layer 608 includes dual cyan and magenta colorants. In another embodiment, first electro-optic layer 604 includes dual yellow and cyan colorants, and second electro-optic layer 608 includes dual magenta and black colorants. In yet another embodiment, first electro-optic layer 604 includes a single cyan colorant, and second electro-optic layer 608 includes dual yellow and magenta colorants. In yet another embodiment, first electro-optic layer 604 includes a single magenta colorant, and second electro-optic layer 608 includes dual yellow and cyan colorants. In yet another embodiment, first electro-optic layer 604 includes dual yellow and magenta colorants, and second electro-optic layer 608 includes dual cyan and black colorants. In yet another embodiment, first electro-optic layer 604 includes dual cyan and magenta colorants, and second electro-optic layer 608 includes dual yellow and black colorants. In other embodiments, other suitable single or dual colorants can be used in first electro-optic layer 604 and second electro-optic layer 608. The use of a black colorant in one of the electro-optic layers including dual colorants provides an improved black optical state compared to an electronic display that does not include a black colorant.

FIG. 18 illustrates another embodiment of an electronic display 620 including two electro-optic layers. Electronic display 620 is similar to electronic display 600 previously described and illustrated with reference to FIG. 17, except that electronic display 620 includes a white reflector layer 622. Transparent TFT layer 610 is arranged on white (i.e., broadband visible range diffuse) reflector layer 622. Due to white reflector 622, electronic display 620 is a reflective electronic display. Thus, in one embodiment electronic display 620 can provide a display having characteristics similar to printing on white paper.

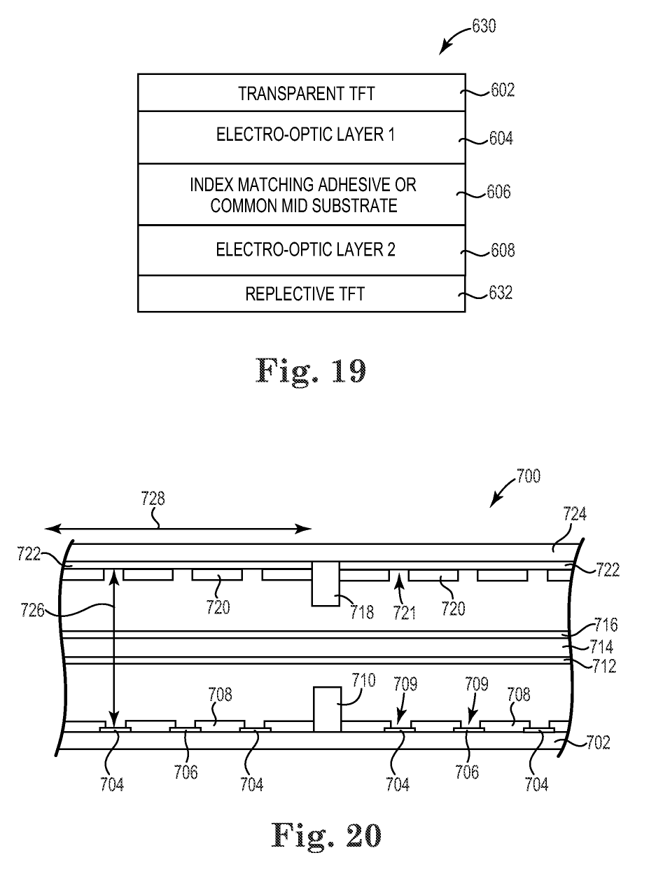

FIG. 19 illustrates another embodiment of an electronic display 630 including two electro-optic layers. Electronic display 630 is similar to electronic display 600 previously described and illustrated with reference to FIG. 17, except that transparent TFT layer 610 is replaced with a reflective TFT layer 632. In this embodiment, the lower electrodes or a patterned dielectric layer for second electro-optic layer 608 are made of white reflective components. Surfaces providing the reflective components can be structured to be diffusive and coated with highly reflective materials to provide scattering across visible wavelengths. Alternatively, or in addition, the dielectric layer can be embedded with scattering particles to serve as a white reflector. Due to reflective TFT layer 632, electronic display 630 is a reflective electronic display. Thus, in one embodiment electronic display 630 can provide a display having characteristics similar to printing on white paper.

FIG. 20 illustrates a cross-sectional view of one embodiment of an electronic display 700 including two electro-optic layers. In one embodiment, electronic display 700 provides electronic display 600, 620, or 630 previously described and illustrated with reference to FIGS. 17-19. Electronic display 700 includes a bottom substrate 702 on which thin film transistors are formed, first electrodes 704, second electrodes 706, a dielectric layer 708 including recess regions 709, pixel sidewalls 710, a third electrode 712, and a common mid substrate 714. In addition, electronic display 700 includes a fourth electrode 716, a top substrate 724 on which thin film transistors are formed, fifth electrodes 722, a dielectric layer 720 including recess regions 721, and pixel sidewalls 718.

First electrodes 704 and second electrodes 706 are interdigitated and formed on the top surface of bottom substrate 702. In one embodiment, first electrodes 704 and second electrodes 706 are similar to interdigitated electrodes 428 and 430 previously described and illustrated with reference to FIG. 10. Each electrode 704 and 706 is electrically coupled to a thin film transistor formed on the top surface of bottom substrate 702. In one embodiment, the thin film transistors are similar to thin film transistors 436 and 438 previously described and illustrated with reference to FIG. 10.

Dielectric layer 708 is formed over first electrodes 704 and second electrodes 706 and structured to provide recess regions 709 exposing portions of each first electrode 704 and each second electrode 706. In one embodiment, recess regions 709 are similar to recess regions 105 previously described and illustrated with reference to FIG. 4 or recess regions 452 previously described and illustrated with reference to FIGS. 11A-11C. Pixel sidewall 710, which is also made of a dielectric material such as the dielectric material of dielectric layer 708, is formed on the top surface of bottom substrate 702 and separates adjacent pixels of electronic display 700 from each other. Third electrode 712 is a continuous electrode formed on the bottom surface of common mid substrate 714. Common mid substrate 714 is parallel to bottom substrate 702. In one embodiment, common mid substrate 714 has a thickness of 150 μm or less.

Fourth electrode 716 is a continuous electrode formed on the top surface of common mid substrate 714. Fifth electrodes 722 are formed on the bottom surface of top substrate 724. Top substrate 724 is parallel to common mid substrate 714 and bottom substrate 702. Each fifth electrode 722 is electrically coupled to a thin film transistor formed on the bottom surface of top substrate 724. The active electrodes for the upper and lower electro-optic layers are aligned within each pixel.

Dielectric layer 720 is formed over fifth electrodes 722 and structured to provide recess regions 721 exposing portions of each fifth electrode 722. In one embodiment, recess regions 721 are similar to recess regions 709 and are aligned with recess regions 709. Pixel sidewall 718, which is also made of a dielectric material such as the dielectric material of dielectric layer 722, is formed on the bottom surface of top substrate 724 and separates adjacent pixels of electronic display 700 from each other. Each fifth electrode 722 extends between adjacent pixel sidewalls 718. Pixel sidewall 718 is aligned with pixel sidewall 710.

Bottom substrate 702, common mid substrate 714, and top substrate 724 each comprise a transparent substrate, such as a glass substrate, a plastic substrate, or a composite substrate (e.g., glass fiber, reinforced plastic, or a glass particle embedded plastic matrix). First electrodes 704, second electrodes 706, third electrode 712, fourth electrode 716, and fifth electrodes 722 each comprise a transparent conductive material, such as Indium Tin Oxide (ITO), poly 3,4-ethylenedioxythiophene (PEDOT), nanomaterial conductors (e.g., silver nanowires or carbon nanotubes), or metal mesh conductors. In one embodiment, the thin film transistors formed on bottom substrate 702 and on top substrate 724 each comprise multi-component oxide (MCO), amorphous silicon, or polysilicon. Dielectric layers 708 and 720 and pixel sidewalls 710 and 718 each comprise a transparent dielectric material. In one embodiment, the dielectric material is a dielectric resin that is patterned using an embossing process or a photolithography process.

A carrier fluid with dual colorants is provided between first and second electrodes 704 and 706 and third electrode 712. In one embodiment, the carrier fluid with dual colorants is similar to the carrier fluid with colorant particles 326 and 328 previously described and illustrated with reference to FIGS. 8A-8C. First electrodes 704 are used to control the movement of one of the colorants, and second electrodes 706 are used to control the movement of the other one of the colorants.

Another carrier fluid with a single colorant is provided between fourth electrode 716 and fifth electrodes 722. In one embodiment, the carrier fluid with a single colorant is similar to the carrier fluid with colorant particles 114 previously described and illustrated with reference to FIGS. 1A-1C. Fifth electrodes 722 are used to control the movement of the single colorant. In one embodiment, the single colorant of the upper electro-optic layer includes a yellow colorant, and the dual colorants of the lower electro-optic layer include a cyan colorant and a magenta colorant. In other embodiments, the dual colorants and the single colorant include other suitable colorants as previously described with reference to FIG. 17.

In one embodiment, the distance (as indicated at 726) between first electrodes 704 (and second electrodes 706) and fifth electrodes 722 is equal to or less than one half the width (as indicated at 728) of each fifth electrode 722, which defines the size of a single pixel. With the distance between first electrodes 704 and fifth electrodes 722 equal to or less than one half the width of each fifth electrode 722, electronic display 700 does not exhibit any serious parallax issues. In addition, by using common mid substrate 714 with continuous third electrode 712 on one side and continuous fourth electrode 716 on the other side, the fabrication process for electronic display 700 is simplified.

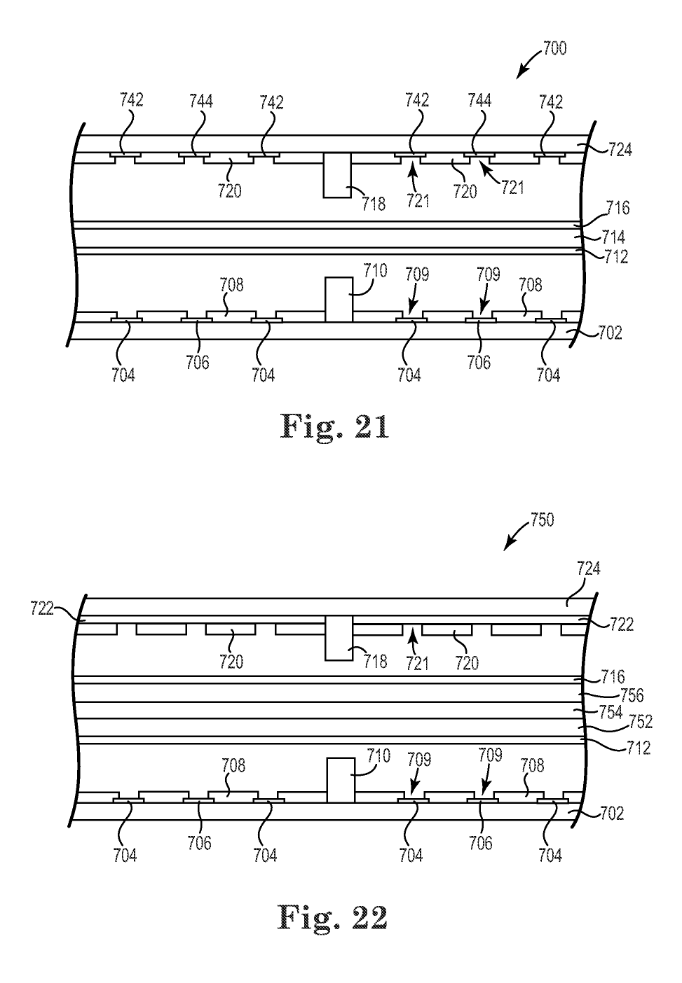

FIG. 21 illustrates a cross-sectional view of another embodiment of an electronic display 740 including two electro-optic layers. In one embodiment, electronic display 740 provides electronic display 600, 620, or 630 previously described and illustrated with reference to FIGS. 17-19. Electronic display 740 is similar to electronic display 700 previously described and illustrated with reference to FIG. 20, except that electronic display 740 includes fifth electrodes 742 and sixth electrodes 744 in place of fifth electrodes 722.

In this embodiment, fifth electrodes 742 and sixth electrodes 744 are interdigitated and formed on the bottom surface of top substrate 724 in a similar manner as first electrodes 704 and second electrodes 706 are formed on the top surface of bottom substrate 702. Each electrode 742 and 744 is electrically coupled to a thin film transistor formed on the bottom surface of top substrate 724 in a similar manner as each electrode 704 and 706 is electrically coupled to a thin film transistor formed on the top surface of bottom substrate 702. The active electrodes for the upper and lower electro-optic layers are aligned within each pixel.

Dielectric layer 720 is formed over fifth electrodes 742 and sixth electrodes 744 and structured to provide recess regions 721 exposing portions of each fifth electrode 742 and each sixth electrode 744. In one embodiment, recess regions 721 are similar to recess regions 709 and are aligned with recess regions 709.

A carrier fluid with dual colorants is provided between fourth electrode 716 and fifth and sixth electrodes 742 and 744. Fifth electrodes 742 are used to control the movement of one of the colorants, and sixth electrodes 744 are used to control the movement of the other one of the colorants. Thus, electronic display 740 uses dual colorants in each electro-optic layer. In one embodiment, the dual colorants of one electro-optic layer include a yellow colorant and a cyan colorant, and the dual colorants of the other electro-optic layer include a magenta colorant and a black colorant. In other embodiments, the dual colorants of each electro-optic layer include other suitable colorants as previously described with reference to FIG. 17.

FIG. 22 illustrates a cross-sectional view of another embodiment of an electronic display 750 including two electro-optic layers. In one embodiment, electronic display 750 provides electronic display 600, 620, or 630 previously described and illustrated with reference to FIGS. 17-19. Electronic display 750 is similar to electronic display 700 previously described and illustrated with reference to FIG. 20, except that in electronic display 750 common mid substrate 714 is replaced with substrates 752 and 756 and an index matching adhesive layer 754.

In this embodiment, each electro-optic layer is fabricated separately. Third electrode 712 is formed on the bottom surface of substrate 752. Fourth electrode 716 is formed on the top surface of substrate 756. Substrates 752 and 756 each comprise a transparent substrate, such as a glass substrate, a plastic substrate, or a composite substrate (e.g., glass fiber, reinforced plastic, or a glass particle embedded plastic matrix). After each electro-optic layer has been fabricated, substrate 756 of the upper electro-optic layer is bonded to substrate 752 of the lower electro-optic layer using index matching adhesive layer 754. Substrates 756 and 752 are aligned and bonded such that pixel sidewalls 718 are aligned with pixel sidewalls 710. Index matching adhesive layer 754 minimizes the Fresnel reflection loss, which allows a maximum amount of light to be introduced for the electro-optic modulation.

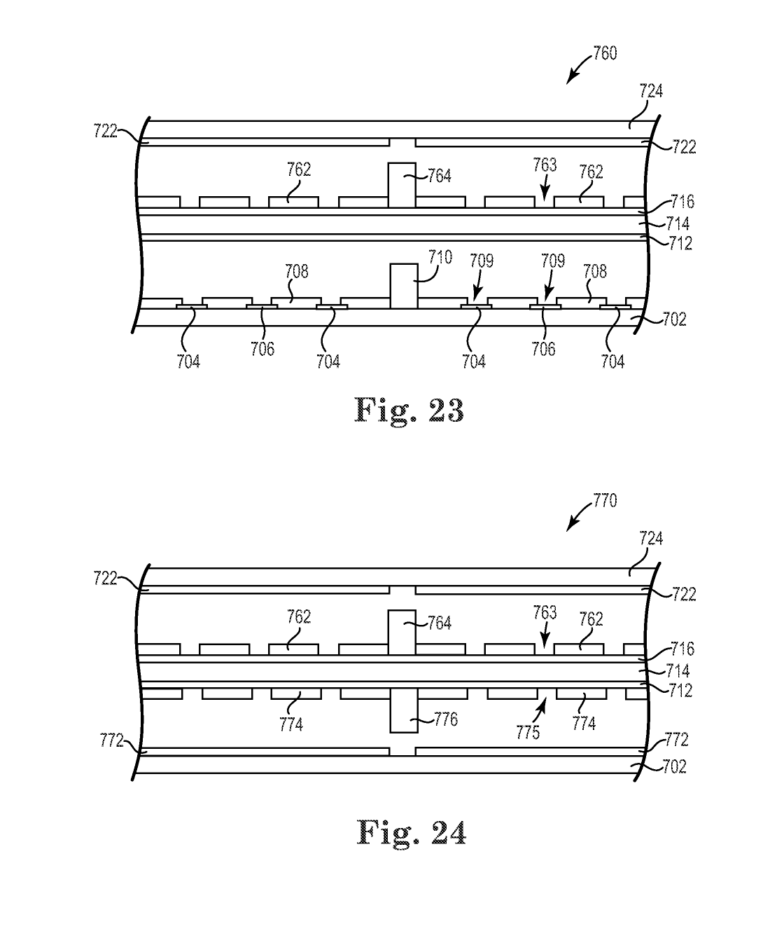

Substrates 752 and 756 and index matching adhesive layer 754 can also be used in place of common mid substrate 714 of electronic display 740 illustrated in FIG. 21 and in place of common mid substrate 714 illustrated in the embodiments illustrated in the following FIGS. 23 and 24.

FIG. 23 illustrates a cross-sectional view of another embodiment of an electronic display 760 including two electro-optic layers. In one embodiment, electronic display 760 provides electronic display 600, 620, or 630 previously described and illustrated with reference to FIGS. 17-19. Electronic display 760 is similar to electronic display 700 previously described and illustrated with reference to FIG. 20, except that in electronic display 760 the dielectric layer and pixel sidewalls of the upper electro-optic layer are formed on fourth electrode 716.

In this embodiment, a dielectric layer 762 is formed over fourth electrode 716 and structured to provide recess regions 763 exposing portions of fourth electrode 716. In one embodiment, recess regions 763 are similar to recess regions 709 and are aligned with recess regions 709. A pixel sidewall 764, which is also made of a dielectric material such as the dielectric material of dielectric layer 762, is formed on fourth electrode 716 and separates adjacent pixels of electronic display 760 from each other. Pixel sidewall 764 is aligned with pixel sidewall 710.

FIG. 24 illustrates a cross-sectional view of another embodiment of an electronic display 770 including two electro-optic layers. In one embodiment, electronic display 770 provides electronic display 600, 620, or 630 previously described and illustrated with reference to FIGS. 17-19. Electronic display 770 is similar to electronic display 760 previously described and illustrated with reference to FIG. 23, except that in electronic display 770 the lower electro-optic layer is configured to control one colorant instead of two.

In this embodiment, the lower electro-optic layer includes first electrodes 722, a dielectric layer 774 including recess regions 775, and pixel sidewalls 776. First electrodes 772 are formed on the top surface of bottom substrate 702. Each first electrode 772 is electrically coupled to a thin film transistor formed on the top surface of bottom substrate 702. The active electrodes for the upper and lower electro-optic layers are aligned within each pixel. Dielectric layer 774 is formed over third electrode 712 and structured to provide recess regions 775 exposing portions of third electrode 712. In one embodiment, recess regions 775 are similar to recess regions 763 and are aligned with recess regions 763.

Pixel sidewall 776, which is also made of a dielectric material such as the dielectric material of dielectric layer 774, is formed on third electrode 712 and separates adjacent pixels of electronic display 700 from each other. Each first electrode 772 extends between adjacent pixel sidewalls 776. Pixel sidewall 776 is aligned with pixel sidewall 764. A carrier fluid with a single colorant is provided between first electrodes 772 and third electrode 712. First electrodes 772 are used to control the movement of the single colorant.

Embodiments provide a color electronic display by stacking two electro-optic layers. By stacking two electro-optic layers, an optically efficient structure providing an improved color gamut (i.e., modulation of every color in every pixel) as well as brightness for color reflective displays is provided. A two layer color electronic display results in less absorption, scattering, and/or reflection compared to displays with more than two layers. In addition, the embodiments provide a color electronic display without parallax issues and having a wide viewing angle.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. An electronic display comprising:
a first display element configured to control a first colorant to provide a transparent optical state and a colored optical state;
a second display element stacked on the first display element and configured to control a second colorant to provide a transparent optical state and a colored optical state;
a transparent first substrate between the first and second display elements;
a transparent second substrate opposite a first side of the first substrate; and
a transparent third substrate opposite a second side of the first substrate,
wherein the first display element comprises:
a continuous first electrode on the first side of the first substrate;
a plurality of first thin film transistors on the second substrate; and
a plurality of second electrodes on the second substrate, each second electrode coupled to a first thin film transistor; and
wherein the second display element comprises:
a continuous third electrode on the second side of the first substrate;
a plurality of second thin film transistors on the third substrate; and
a plurality of fourth electrodes on the third substrate, each fourth electrode coupled to a second thin film transistor.

2. The electronic display of claim 1, wherein one of the first display element and the second display element is configured to control a third colorant to provide a transparent optical state and a colored optical state.

3. The electronic display of claim 1, wherein the first display element is configured to control a third colorant to provide a transparent optical state and a colored optical state, and
wherein the second display element is configured to control a fourth colorant to provide a transparent optical state and a colored optical state.

4. The electronic display of claim 3, wherein the first colorant, the second colorant, the third colorant, and the fourth colorant each comprise a different one of a cyan colorant, a magenta colorant, a yellow colorant, and a black colorant.

5. The electronic display of claim 3, wherein the first colorant, the second colorant, the third colorant, and the fourth colorant each comprise a different one of a red colorant, a green colorant, a blue colorant, and a white colorant.

6. The electronic display of claim 3, wherein the first colorant, the second colorant, the third colorant, and the fourth colorant each comprise a different one of a subtractive colorant or an additive colorant.

7. The electronic display of claim 1, further comprising:
a transparent fourth substrate coupled to the first substrate,
wherein the first electrode is formed on the first substrate, and
wherein the third electrode is formed on the fourth substrate.

8. The electronic display of claim 1, further comprising:
a reflector coupled to the second substrate.

9. The electronic display of claim 1, wherein the first display element comprises a first structured dielectric layer over the plurality of second electrodes, the first structured dielectric layer configured to expose portions of the plurality of second electrodes, and
wherein the second display element comprises a second structured dielectric layer over the plurality of fourth electrodes, the second structured dielectric layer configured to expose portions of the plurality of fourth electrodes.

10. The electronic display of claim 1, wherein the first display element comprises a first structured dielectric layer over the first electrode, the first structured dielectric layer configured to expose portions of the first electrode, and
wherein the second display element comprises a second structured dielectric layer over the third electrode, the second structured dielectric layer configured to expose portions of the third electrode.

11. The electronic display of claim 1, wherein a distance between a second electrode and a fourth electrode is approximately equal to or less than one half a width of a second electrode.

12. The electronic display of claim 1, wherein the first substrate, the second substrate, and the third substrate each comprise one of a glass substrate, a plastic substrate, and a composite substrate,
wherein the first electrode, the second electrodes, the third electrode, and the fourth electrodes each comprise one of Indium Tin Oxide (ITO), poly 3,4-ethylenedioxythiophene (PEDOT), nanomaterial conductors, and metal mesh conductors, and
wherein the first thin film transistors and the second thin film transistors each comprise one of multi-component oxide (MCO), amorphous silicon, and polysilicon.

13. An electronic display comprising:
a transparent first substrate;
a plurality of thin film transistors arranged on the first substrate;
a plurality of first electrodes arranged on the first substrate, each of the plurality of first electrodes coupled to a thin film transistor;
a transparent second substrate;
a transparent continuous second electrode on a first side of the second substrate facing the first substrate;
a transparent continuous third electrode on a second side of the second substrate opposite the first side of the second substrate;
a transparent third substrate;
a plurality of thin film transistors arranged on the third substrate;
a plurality of fourth electrodes arranged on the third substrate, each of the plurality of fourth electrodes coupled to a thin film transistor;
a first fluid with a first colorant between the first electrodes and the second electrode; and
a second fluid with a second colorant between the third electrode and the fourth electrodes.

14. The electronic display of claim 13, further comprising:
a plurality of fifth electrodes arranged on the third substrate, each of the plurality of fifth electrodes interdigitated with one of the plurality of fourth electrodes; and
a plurality of sixth electrodes arranged on the first substrate, each of the plurality of sixth electrodes interdigitated with one of the plurality of first electrodes,
wherein the second fluid between the third electrode and the fourth electrodes comprises a fluid with the second colorant and a third colorant, and
wherein the first fluid between the first electrodes and the second electrode comprises a fluid with the first colorant and a fourth colorant.

15. The electronic display of claim 13, further comprising:
a transparent fourth substrate attached to the second substrate via a transparent adhesive material,
wherein the second electrode is formed on the second substrate, and
wherein the third electrode is formed on the fourth substrate.

16. A method for fabricating an electronic display, the method comprising:
providing a continuous first electrode on a first side of a transparent first substrate;
providing a continuous second electrode on a second side of the first substrate opposite the first side of the first substrate;
forming thin film transistors and third electrodes on a transparent second substrate;
forming thin film transistors and fourth electrodes on a transparent third substrate;
aligning the third electrodes and the fourth electrodes such that the third electrodes face the first electrode and the fourth electrodes face the second electrode;
filling a space between the first electrode and the third electrodes with a fluid with a first colorant; and
filling a space between the second electrode and the fourth electrodes with a fluid with a second colorant.

17. The method of claim 16, wherein filling the space between the first electrode and the third electrodes comprises filling the space between the first electrode and the third electrodes with a fluid with the first colorant and a third colorant.

18. The method of claim 17, wherein filling the space between the second electrode and the fourth electrodes comprises filling the space between the second electrode and the fourth electrodes with a fluid with the second colorant and a fourth colorant.

19. The method of claim 16, further comprising:
structuring a first dielectric layer on the second substrate, the first dielectric layer defining recess regions exposing portions of the third electrodes to the fluid with the first colorant; and
structuring a second dielectric layer on the third substrate, the second dielectric layer defining recess regions exposing portions of the fourth electrodes to the fluid with the second colorant.

20. The method of claim 16, further comprising:
structuring a first dielectric layer on the first side of the first substrate, the first dielectric layer defining recess regions exposing portions of the first electrode to the fluid with the first colorant; and
structuring a second dielectric layer on the second side of the first substrate, the second dielectric layer defining recess regions exposing portions of the second electrode to the fluid with the second colorant.
